(19) United States
(12) Patent Application Publication
(10) Pub. No.: US 2007/0069389 A1
(43) Pub. Date: Mar. 29, 2007

(54) Stackable device, device stack and method for fabricating the same

(76) Inventors: Alexander Wollanke, Dresden (DE); Claudia Luhmann, Dresden (DE); Thorsten Meyer, Regensburg (DE)

Correspondence Address: PATTERSON & SHERIDAN, LLP;Gero McClellan / Infineon / Qimonda, 3040 POST OAK BLVD.,, SUITE 1500, HOUSTON, TX, 77056, US

(21) Appl. No.: 11/227,882

(22) Filed: Sep. 15, 2005

(51) Int. Cl. H01L 23/52

(52) U.S. Cl. 257/777

(57) ABSTRACT

The present invention generally relates to a method for fabricating a stackable packaged device and a method for producing a packaged device stack utilizing stackable packaged devices. The present invention further refers to a stackable packaged device and a packaged device stack.

### BACKGROUND OF THE INVENTION

1. Field of the Invention

The present invention relates to a stackable device, a packaged device stack, and methods for producing the same.

2. Description of the Related Art

In order to be able to provide complete semiconductor systems, stacking of single (one-die) chip packages comes into focus to satisfy the demand for higher integration and multi-functional devices. One way to provide a multi-functional system is to stack single packages (already packaged), each including one chip, onto each other to obtain a device stack with an increased performance in an optimized device size.

Another approach is the stacking of a number of single (unpackaged) chips in a single package in order to provide a multi-chip-system in one single device. One issue usually is that it is difficult to test the unpackaged chips before stacking as it is cost intensive to electrically contact the chips as bare dies which would increase the total manufacturing costs. After assembling, in the case that one of the chips is faulty, the complete stacked device would normally have to be discarded. Therefore, the package stacking is preferred as the packaged single dies can be tested in a cost-efficient manner prior to their stacking onto the device stack in such a way that only dies which are known to be good (known good dies) are used in order to produce a device stack.

Conventionally, the stacking of packages is performed by means of interposers which are located between two stacked packages in order to provide the electrical connection of each of the stacked packages. The interposers are expensive to produce and to handle.

The document US 2005/0077632 A1 provides a method for producing a multi-chip module including the application of at least one contact elevation on a substrate, the application and patterning of a rewiring device onto the substrate, and at least one contact elevation with the provision of a contact device on the at least one contact elevation. The method also includes the application of a semiconductor chip onto the substrate with electrical contact connection of the rewiring device, the application of an encapsulating device which is not electrically conductive onto the semiconductor chip, the substrate, the rewiring device and the at least one contact elevation. The contact device on the at least one contact elevation touches a first surface of the encapsulation device. At least one of at least the first two (application) steps is repeated, in the first surface of the encapsulation device serving as a substrate and the correspondingly produced rewiring device making electrical contact with the contact device of the at least one contact elevation of the underlying plane. The method proposed therein uses bare dies in order to build up the multi-chip module. As described above, bare dies are difficult to be subjected to functional test, since their electrical contacting is time-consuming and requires special expensive contacting equipment.

Therefore there is a need to provide a method for fabricating a stackable packaged device which is easy to produce and which can be tested before being stacked onto a multi-chip device. In addition, there is a need to provide a method for fabricating a stackable device which is to be adapted to be stacked without requiring an extra interposer, a rewiring layer or the like.

### SUMMARY OF THE INVENTION

The present invention generally relates to a method for fabricating a stackable packaged device and a method for producing a packaged device stack utilizing stackable packaged devices. The present invention further refers to a stackable packaged device and a packaged device stack.

In one embodiment, a method for fabricating a stackable packaged device comprises the sequential steps of: (a) providing a carrier substrate, (b) providing a plurality of conducting contact elements on a first surface of the carrier substrate, (c) placing at least one chip on the first surface of the carrier substrate such that the plurality of conducting contact elements and the at least one chip are arranged on different regions of the first surface of the carrier substrate, (d) providing an encapsulation on the first surface of the carrier substrate to cover a remaining first surface that is not covered by the at least one chip and the plurality of conducting contact elements, to cover the at least one chip, and to cover at least portions of the plurality of conducting contact elements while a portion of each of the plurality of conducting contact elements is not covered by the encapsulation to allow electrical contacting of each of the plurality of conducting contact elements, wherein an exposed surface of the encapsulation and the portion of each of the plurality of conducting contact elements not covered by the encapsulation form a first device surface, (e) removing the carrier substrate to release a second device surface that opposes the first device surface, and (f) applying a conductive redistribution structure on the second device surface to provide electrical connection between the plurality of conducting contact elements and integrated circuits of the at least one chip.

In another embodiment, a method for providing of a multi-chip packaged device stack comprises the sequential steps of: (i) fabricating a plurality of stackable packaged devices with a plurality of conductive contact elements on a first device surface of each of the plurality of stackable packaged devices, and a plurality of conductive contacting structures on a second device surface of each of the plurality of stackable packaged devices, (ii) testing the plurality of stackable packaged devices to select a plurality of stackable packaged devices that pass the testing criteria, and (iii) stacking a selected stackable packaged device that passes the testing criteria on a stack of stackable packaged devices with at least one stackable package device by coupling the plurality of conductive contacting structures on the second device surface of the selected stackable packaged device with the plurality of conductive contact elements on the first device surface of a stackable packaged device on the top of the stack of stackable packaged devices with at least one stackable package device to form a multi-chip packaged device stack.

In another embodiment, a stackable packaged device, fabricated by the sequential steps comprises of: (a) providing a carrier substrate, (b) providing a plurality of conducting contact elements on a first surface of the carrier substrate, (c) placing at least one chip on the first surface of the carrier substrate such that the plurality of conducting contact elements and the at least one chip are arranged on different regions of the first surface of the carrier substrate, (d) providing an encapsulation on the first surface of the carrier substrate to cover a remaining first surface that is not covered by the at least one chip and the plurality of conducting contact elements, to cover the at least one chip, and to cover at least portions of the plurality of conducting contact elements while a portion of each of the plurality of conducting contact elements is not covered by the encapsulation to allow electrical contacting of each of the plurality of conducting contact elements, wherein an exposed surface of the encapsulation and the portion of each of the plurality of conducting contact elements not covered by the encapsulation form a first device surface, (e) removing the carrier substrate to release a second device surface that opposes the first device surface, and (f) applying a conductive redistribution structure on the second device surface to provide electrical connection between the plurality of conducting contact elements and integrated circuits of the at least one chip.

In another embodiment, a stackable packaged device comprises an encapsulation having a first surface and a second surface, a plurality of conducting contact elements embedded in the encapsulation such that the plurality of conducting contact elements extend through the encapsulation from the first to the second surface, one chip embedded in the encapsulation, wherein the at chip having a plurality of contacts which are accessible on the second surface of the encapsulation, and a redistribution structure on the second surface to provide electrical connection to the plurality of conducting contact elements and to the plurality of contacts of the chip.

In another embodiment, a multi-chip packaged device stack comprises a plurality of stackable packaged devices with a plurality of conductive contact elements on a first device surface of each of the plurality of stackable packaged devices, and a plurality of conductive contacting structures on a second device surface of each of the plurality of stackable packaged devices, wherein the plurality of stackable packaged devices have been tested and pass the testing criteria, and the plurality of stackable packaged devices stacked vertically with the plurality of conductive contacting structure on the second device surface of a selected stackable packaged device coupled to the plurality of conductive contact elements on the first device surface of a stackable packaged device disposed right below the selected stackable packaged device to form the multi-chip packaged device stack.

In yet another embodiment, a stackable package device comprises an encapsulation having a first surface and a second surface, wherein the encapsulation has embedded one chip and the chip having a plurality of contacts which are accessible on the second surface of the encapsulation, means of electrically contacting the at least one chip from the second surface, means of electrically contacting the at least one chip from the first surface, and means of electrically testing the at least one chip.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIGS. 1A to 1I show the process states of the method for fabricating a stackable device according to one embodiment of the present invention; and

FIG. 2 shows the carrier substrate including the stackable packaged devices before the application of the redistribution structure.

### DETAILED DESCRIPTION OF THE PREFERRED EMBODIMENT

In one embodiment of the present invention, a method for providing a multi-chip packaged device stack is provided. The method comprises the steps of fabricating a number of stackable packaged devices and of stacking the stackable devices such that the contact elements and structures of two adjacent devices come into contact with one another.

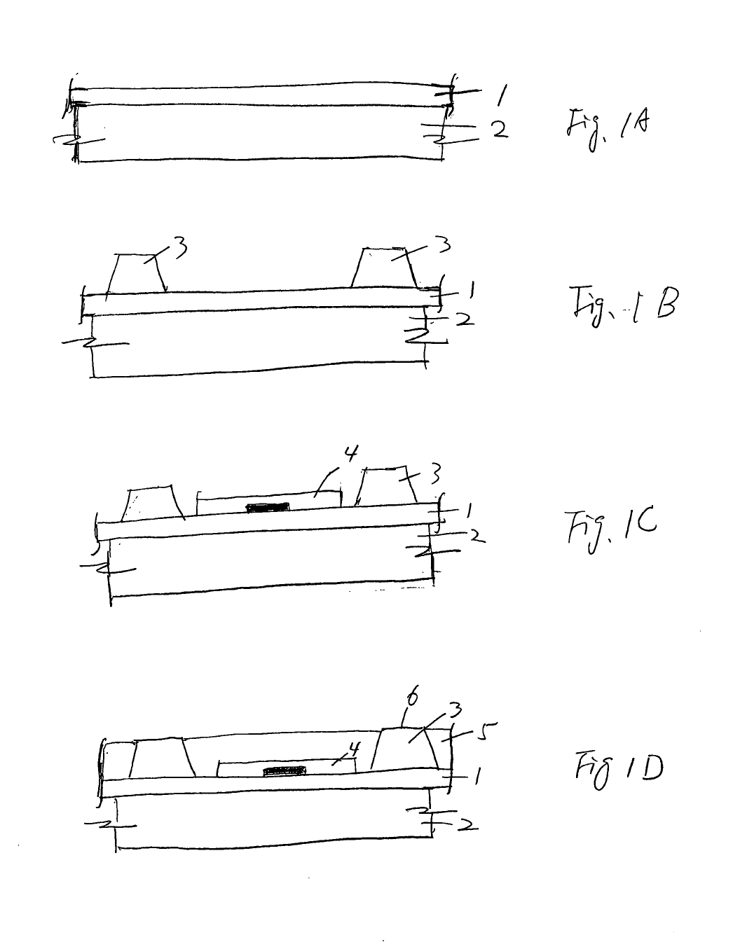

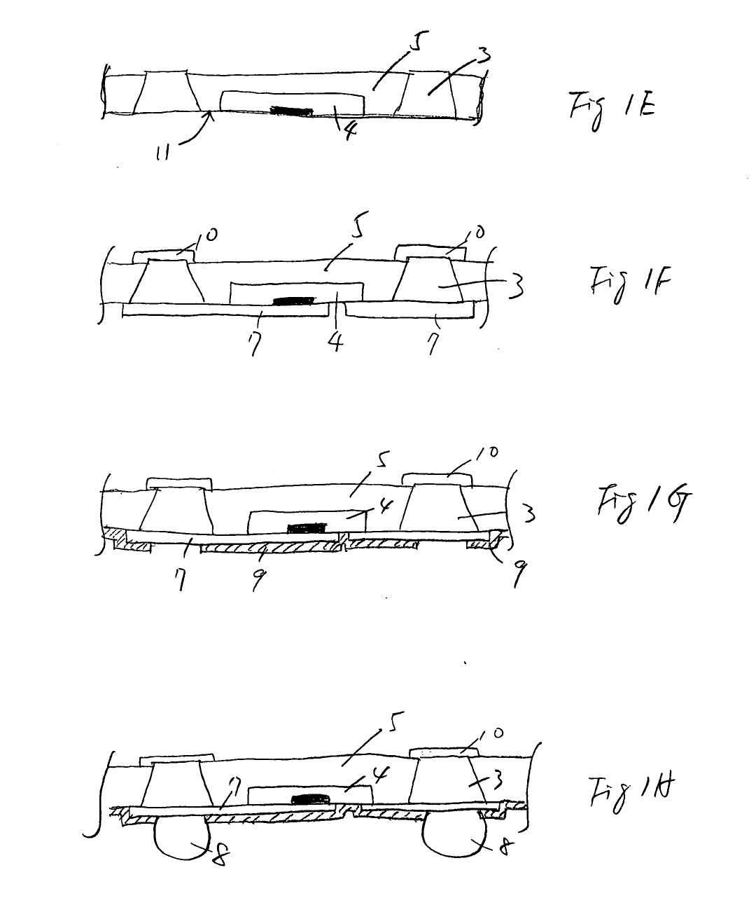

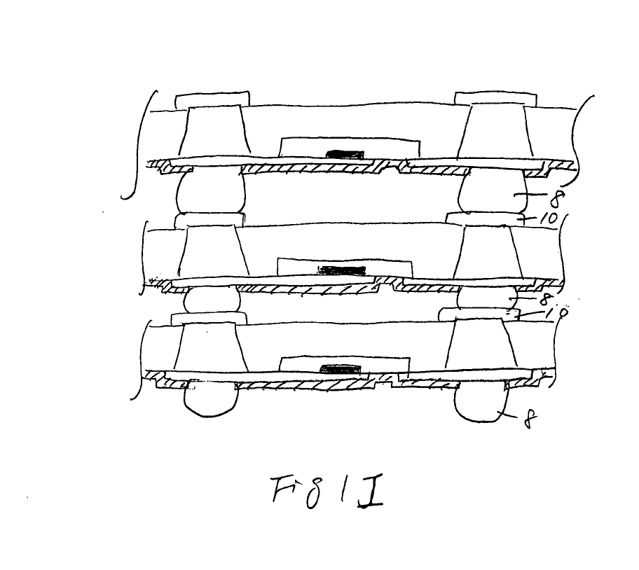

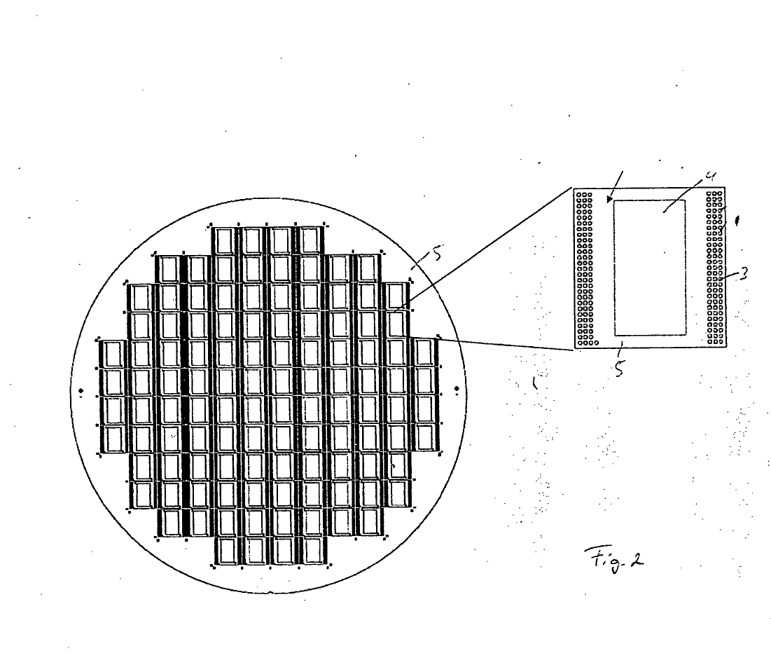

In the FIGS. 1A to 1I, the method states of the process for fabricating a stackable device and the stacking of the stackable devices are depicted. As shown in FIG. 1A, a carrier substrate is provided which is to serve as a carrier means for one or a plurality of package devices (or package) to be fabricated at a time. The place on which a single package is formed is referred to herein as a package location. The carrier substrate in the illustrated embodiment is provided as a releasable foil 1 which is supported by a plane rigid support 2 on which the releasable foil 1 is applied. The releasable foil 1 is selected to be compatible with the subsequent process steps for building up a packaged device especially with a heating process. Instead of the releasable foil 1, other carrier substrates may be selected which can be released in an easy manner after a encapsulation is applied in one of the subsequent process steps which finally form the packaged body as explained below.

In FIG. 1B, the process state after the application of contact elements 3 is shown. The contact elements 3 are applied to serve as a through-contact extending through the package to be formed. The contact elements 3 are applied by a screen-printing, stencil-printing, dispensing, moulding process, or the like, by means of a conducting material. For example, the printing may be performed by applying a printing mask on the surface of the carrier substrate (releasable foil 1) and by applying the conducting material on the printing mask. Locations on which a contact element should be formed on the carrier substrate are provided as through-holes through the printing mask which are filled as the conducting material is applied. By removing the printing mask, the contact elements remain on the carrier substrate as defined by the printing mask. After the conducting material has been applied, it is cured or hardened depending on the conducting material. Instead of curing the conducting material, drying or another process may be performed which results in a hardened contact element. For some embodiments, the conducting material is made from at least one of a conductive adhesive, a conductive epoxy material, a metal-doped material (e.g. silver), and a conductive polymer which can be cured or hardened. As is known, as the conducting material which may be used to form the contact elements 3, different conductive materials may be applied which can be deposited by at least one of a screen-printing, a stencil-printing, a dispensing and a moulding process and which can be cured to withstand the preceding processes as described below.

As shown in the process state of FIG. 1C, as a next process step a chip 4 including an integrated circuit is applied on the releasable foil 1 of the carrier substrate. The active surface, i.e. the surface from which the integrated circuit is implemented, is thereby attached to the surface of the releasable foil 1. This means that the chip 4 is attached up-side-down onto the carrier substrate 1, 2. Although in FIG. 1C only the attaching of a single chip 4 onto the carrier substrate 1 is shown, the process step of attaching the chip 4 may be repeated a number of times for each package location over the total size of the carrier substrate 1 such that subsequent process steps can be preferably simultaneously applied for fabricating a number of stackable devices (see FIG. 2).

In a next process step as shown with the process state of FIG. 1D, an encapsulation material 5 is applied onto the whole surface of the carrier substrate 1, 2 the contact elements 3 and the chips 4. The encapsulation material 5 is hardened by curing, drying or a similar technique in order to provide a robust body of the packaged device to be formed. Preferably, after the encapsulation process, the device surface is planarized such that the contact elements are exposed to provide electrical contacts. The encapsulation material 5 should be applied in such a way that a portion 6 of the contact element is later exposed which can be achieved by applying the encapsulation material 5 in such a way that the portion of the contact element 3 remains uncovered or in such a way that the encapsulation material 5 is applied and thinned afterwards e.g. by polishing and/or plasma treatment and the like, so that the upper portions 6 of the contact elements 3 are exposed finally. The upper portions 6 of the contact elements 3 are preferably flush with a first surface 12 of the encapsulation material 5 but it is also possible that the portion 6 of the contact element 3 is elevated or lowered with regard to the first surface 12 of the encapsulation material 5.

As shown in the process state of FIG. 1E, the releasable foil 1 is released such that an opposing second surface 11 of the encapsulation material 5 in which the chips 4 are embedded is uncovered. For some embodiments, the releasable foil 1 can be stripped off the hardened encapsulation material 5. In case that the carrier substrate 2 is formed by another material, other ways of removing the carrier substrate may be adequate. For example, a rigid carrier substrate 2 made of metal, semiconductor, or polymer material, and the like, can be removed by etching or polishing processes. After removing the releasable foil, a wafer or another artificial form (e.g. a rectangle arrangement) can be obtained including the plurality of chips 4 embedded on their package locations.

Thereafter, a conductive redistribution structure 7 is applied onto the second surface 11 of the encapsulation material 5 in order to provide electrical connection between the contact elements 3 and the integrated circuits of the chips 4 (see FIG. 1F) as well as between contact pads (not shown) and the integrated chips and/or between at least two adjacent similar or different chips in the same level. With the same or a separate process, on the first surface of the encapsulation material 5, the upper portions 6 of the contact elements 3 may be metalized to form a metal pad 10 which allows soldering. One of the objectives of the present invention to is provide a multi-chip packaged device stack which is easy to produce and having a low total height and wherein there is no need to provide an interposing means to establish the electrical connection of each of the stacked devices. Soldering stacked packaged devices gives lower stack height and allows the elimination of interposers.

The redistribution structure 7 applied on the second surface 11 of the encapsulation material 5 can be mono-layered or multi-layered (e.g., with each layer insulated by an insulation layer) to provide the respective redistribution wiring. The redistribution structure 7 as well as the metal pad 10 may be applied by at least one of a plating, a sputtering and a printing process as known in the art. Preferably, a contacting structure is applied to provide an electrical contact to at least one of the contact elements and the chip and/or between at least two adjacent similar or different chips in a same level. Therefore, it is possible to provide a contact to the integrated circuit on the chip and/or to the contact element which may be in contact with further devices. At least one of a solder bump, a conductive polymer bump, and a stud bump is applied as the contacting structure. In particular, a solder bump may be applied as the contacting structure by which the stackable device can be soldered to a further substrate or to another stackable device.

In order to provide solder balls on predetermined planes of the rewiring structure to provide a contact with the redistribution structure 7, solder balls 8 are provided. As shown in the process state of FIG. 1G, a solder stop layer 9 is applied to define the predetermined places on which the solder balls 8 are to be placed.

In a next process step as shown in FIG. 1H, the solder balls 8 are arranged on the places defined by the solder stop layer 9. The solder balls 8 can be applied on the contact areas of the rewiring structure 7 in which the contact elements 3 are arranged as well as in areas of additional contact pads (not shown) defined by the redistribution structure 7. The solder balls 8 may be used to provide an external contacting of the packaged integrated circuit. The solder balls 8 can further be connected with metal pads 10 defined on the upper portion 6 of the contact elements 3 of a further packaged device to obtain a stacked arrangement of packaged chips.

In case a plurality of package devices has been provided thereby, a sawing or dicing process can be performed to separate the package locations which define the package devices.

In a next step, a number of stackable devices as fabricated by the method steps illustrated in the FIGS. 1A to 1H is stacked as shown in FIG. 2I. The stacking is performed by soldering a packaged device with its solder balls 8 onto the metal pads 10 of a further stackable packaged device such that a device stack is obtained. In FIG. 1I, the stacking of similar stackable devices in order to obtain a multi-chip device is illustrated. It is also possible that different stackable packaged devices are stacked so as to obtain a multi-chip device stack implementing a system wherein the different functionalities are included in different stackable device packages. The stackable devices as shown in FIG. 1I can be soldered on top of a stackable device arranged below the respective device and can also be used to solder the multichip device stack onto a printed circuit board and such like. Such multichip devices can be assembled onto a printed circuit board much like a single packages.

In FIG. 2, the carrier substrate is illustrated prior to the appliance of the redistribution structure. The carrier substrate preferably has the shape of a wafer or any other artificial form (e.g. a rectangle arrangement) on which the contact elements and the chips 4 are arranged and encapsulation material 5 is applied on the chips 4 and the contact elements. Thereby, a number of packaged dies are obtained simultaneously.

Particularly, the process steps of applying the contact elements 3 by a screen-printing, stencil-printing, dispensing, or moulding process and of applying the encapsulation material 5 on the carrier substrate renders the fabricating process for the stackable package devices a suitable process for mass production of stackable packaged integrated circuits. The encapsulation process may be performed substantially over the total area of the carrier substrate such that the chips and the contact elements are embedded in the encapsulation material 5. After removing the carrier substrate, the chips are still fixed and the bare silicon (the edge sides and the back side) is protected within the encapsulation material 5 which is formed as one plate. The plate itself serves as a new substrate wafer or an other artificial form (e.g. a rectangle arrangement) for depositing the redistribution structure 7 wherein a conventional lithographic process can be applied such as plating, sputtering or printing. The provision of the solder stop layer 8 and the solder balls on the new substrate wafer or any other artificial form (e.g. a rectangle arrangement) formed by the encapsulation material 5 can also be performed before separating the packages from each other. The packages can be separated by means of a sawing or dicing process as commonly used in the art.

The chips 4 attached to the carrier substrate are separated before and may be tested dies known to be good by means of a front end wafer testing process or a bare die testing process. Further, it is also possible to use non-tested bare dies and package them according to the method of the present invention. In this case, the untested stackable packaged devices formed by the process described above may be tested for correct functionality prior to stacking them onto each other to obtain the multi-chip device of the present invention.

Preferably, a testing of the stackable devices may be performed prior to the step of stacking the devices, wherein the subsequent stacking is only performed with the stackable devices which are tested and found to be correctly functioning devices. This allows for omission of the step of testing bare dies which is time-consuming and requires expensive testing equipment. As according to the present invention the testing may be performed with packaged stackable devices, the testing can be performed in a more inexpensive manner without resulting in a reduced yield of the stacking process.

The method of the present invention provides an improved way of fabricating a packaged device which includes through-contacts which may be used in order to provide an electrical connection to further packaged devices stacked on top of the packaged device. In order to provide the contact element on the carrier substrate, a variety of techniques can be applied without the need of considering the compatibility to existing structures as well as preceding process steps. The step of removing the carrier substrate leaves a device with a low height which varies in the range of the height of the chip such that a device stack including devices fabricated by the above-described method has a reduced total height compared to conventional device stacks which include interposers and/or spacers and/or rewiring layers and/or wire bonds (plus additional protection moulding). Furthermore, it is advantageous that a chip can be encapsulated in order to obtain a stackable device without being tested prior thereto as a bare die as the process steps of the method according to the present invention are inexpensive, the testing of the correct functionality of the single chip can be easier performed after packaging the single chip (die) in the stackable device such that a discarding of the packaged die would not incur substantial costs. Therefore, it is no longer necessary to provide dies known to be good in order to build up a device stack in an efficient manner.

While the foregoing is directed to embodiments of the present invention, other and further embodiments of the invention may be devised without departing from the basic scope thereof, and the scope thereof is determined by the claims that follow.

What is claimed is:

1. A method for fabricating one or more stackable devices, comprising:
(a) providing a carrier substrate;
(b) forming a plurality of conducting contact elements on a first surface of the carrier substrate;
(c) placing at least one integrated circuit (IC) device on the first surface of the carrier substrate;
(d) forming an encapsulation layer on the first surface of the carrier substrate to cover the IC device, and at least a portion of the first surface not occupied by the contact elements and IC device, wherein a portion of each of the plurality of conducting contact elements is exposed through the encapsulation layer;
(e) removing the carrier substrate to expose a second device surface that opposes the first device surface;
(f) applying a conductive redistribution structure on the second device surface to provide electrical connection between the plurality of conducting contact elements and the IC device; and
(g) forming conductive contacting structures electrically coupled to the conductive redistribution structure to provide external electrical contacting of the IC device.

2. The method of claim 1, wherein the plurality of conducting contact elements are applied by a method selected from the group consisting of screen printing, stencil printing, dispensing process and mould process using a conducting material.

3. The method of claim 2, wherein the plurality of conducting contact elements are made of material comprises at least one material selected from the group consisting of conductive paste, conductive adhesive, conductive epoxy material, metal-doped material, and conductive polymer, wherein the at least one material can be cured or hardened.

4. The method of claim 1, wherein:
the encapsulation layer is formed over the entire portion of the conducting contact elements; and
the portion of each of the plurality of conducting contact elements is exposed by removing some portion of the encapsulation layer.

5. The method of claim 1, wherein:
a plurality of IC devices is placed on the carrier substrate as a wafer structure; and
subsequently, the encapsulation layer is formed over the IC devices.

6. The method of claim 5, further comprising:
dividing the wafer structure to produce a plurality of stackable devices;
wherein each stackable device comprises at least one of the IC devices, at least some conducting contact elements exposed through the encapsulation layer on a first stackable device surface, and conductive contacting structures on a second stackable device surface to provide external electrical contacting the at least one of the IC devices.

7. A method for fabricating a stacked device comprising multiple stackable devices, comprising:
(i) fabricating a plurality of stackable packaged devices with a plurality of conductive contact elements on a first device surface of each of the plurality of stackable packaged devices, and a plurality of conductive contacting structures on a second device surface of each of the plurality of stackable packaged devices;
(ii) testing the plurality of stackable packaged devices to identify a plurality of stackable packaged devices that pass the testing criteria; and
(iii) stacking identified stackable packaged devices that pass the testing criteria, wherein the conductive contacting structures of a first identified stackable packaged device are coupled to the conductive contact elements of a second identified stackable packaged device to form the stacked device.

8. The method of claim 7, wherein step (iii) is repeated until the multi-chip packaged device stack contains a desired number of stackable packaged devices.

9. The method of claim 7, wherein fabricating the plurality of stackable packaged devices comprises:
placing a plurality of integrated circuit devices on a first surface of a carrier substrate on which the conductive contact elements are formed;
encapsulating the integrated circuit devices with an encapsulation material through which portions of the contact elements are exposed; and
removing the carrier substrate from the encapsulated integrated circuit devices.

10. The method of claim 9, wherein encapsulating the integrated circuit devices comprises a process selected from the group consisting of moulding process, pouring process and printing process.

11. A stackable packaged device, comprising:
one or more integrated circuit (IC) devices encapsulated in an encapsulation material;
a plurality of conducting contact elements partially exposed through the encapsulation material to provide electrical contact with the IC devices; and
a plurality of conducting structures on a surface of the package opposite partially exposed contact elements to provide electrical contact with the IC devices, wherein the conducting structures are arranged to electrical couple with conducting contact elements of another stackable packaged device when the stackable packaged devices are stacked.

12. The stackable packaged device of claim 11, further comprising a redistribution structure to provide electrical connection between the plurality of conducting contact elements and the IC device.

13. The stackable packaged device of claim 11, wherein the one or more IC devices comprises a plurality of IC devices.

14. The stackable packaged device of claim 13, wherein the plurality of IC devices comprise different type IC devices.

15. A multi-chip packaged device stack, comprising:
a plurality of stackable packaged devices, each comprising one or more integrated circuit (IC) devices encapsulated in an encapsulation material,
a plurality of conducting contact elements partially exposed through the encapsulation material to provide electrical contact with the IC devices, and
a plurality of conducting structures on a surface of the package opposite partially exposed contact elements to provide electrical contact with the IC devices; wherein the plurality of stackable packaged devices are stacked with the conducting structures of at least one of the stackable packaged devices is electrically coupled with the conducting contact elements of at least one other of the stackable packaged devices.

16. The multi-chip packaged device stack of claim 15, wherein the plurality of stackable packaged devices comprise different types of stackable packaged devices.

17. The multi-chip packaged device stack of claim 16, wherein at least two of the stackable packaged devices comprise different types of IC devices.

18. The multi-chip packaged device stack of claim 15, wherein at least one of the stackable packaged devices comprises a plurality of IC devices.

19. The multi-chip packaged device stack of claim 18, wherein at least one of the stackable packaged devices comprises a plurality of IC devices of different types.

20. A stackable package device, comprising;
an encapsulation layer having a first surface, wherein the encapsulation layer has embedded at least one integrated circuit (IC) device;
first means, exposed through the first surface of the encapsulation layer, for electrically contacting the IC device through the first surface; and
second means for electrically contacting the at least one IC device on a device surface opposing the first surface of the encapsulation layer, wherein the second means are configured to electrically couple to the first means of another stackable packaged device when the devices are stacked.
